(19) United States
(12) Patent Application Publication
(10) Pub. No.: US 2004/0201394 A1
(43) Pub. Date: Oct. 14, 2004

(54) Method and system for improving testability and reducing test time for packaged integrated circuits

(76) Inventor: John A. Benavides, Garland, TX (US)

Correspondence Address: HEWLETT-PACKARD DEVELOPMENT COMPANY, Intellectual Property Administration, P.O. Box 272400, Fort Collins, CO, 80527-2400, US

(21) Appl. No.: 10/414,196

(22) Filed: Apr. 14, 2003

(51) Int. Cl. G01R 31/26

(52) U.S. Cl. 324/765

(57) ABSTRACT

An embodiment of this invention provides a circuit and method for improving testability and reducing test time for packaged integrated circuits. An LED is physically mounted to a test socket. One lead of the LED is electrically connected to a positive voltage through a pin on the socket. The other lead of the LED is electrically connected to a driving device physically located on the packaged IC. A packaged IC is inserted in the socket. The packaged IC runs a self-test on itself. If the self-test is positive, the driving device activates the LED.

### FIELD OF THE INVENTION

This invention relates generally to packaged integrated electronic circuits. More particularly, this invention relates to improving the testability and the time required to test packaged integrated electronic circuits.

### BACKGROUND OF THE INVENTION

Very Large Scale Integrated (VLSI) chips may contain millions of transistors and electrical connections. Because VLSI chips may be so complex, a great deal of testing may be required to verify that a particular chip is fully functional. The time required to test an integrated circuit (IC) may increase the cost of an IC. As a result, it is desirable to reduce the time required to test an IC.

ICs are typically manufactured on a silicon wafer. Each silicon wafer may contain dozens of individual ICs. These ICs may be microprocessors, DRAMs (Dynamic Random Access Memory), SRAMs (Static Random Access Memory), or other types of ICs. The individual ICs on a silicon wafer are usually tested before the wafer is cut into separate, individual ICs. After all the ICs on the wafer are tested, the wafer is cut into separate, individual ICs and the ICs that passed the tests during wafer test are packaged.

Next, packaged ICs are tested. Packaged ICs are usually placed in a socket that is connected to external test equipment. The external test equipment applies power and signals to operate and test packaged ICs. The tests applied by test equipment can be very complex and as a result may require a relatively great deal of time to complete testing. Before applying the complete suite of tests found on external test equipment, it would be helpful to know if the packaged IC has basic functionality. For example, determining if the packaged IC is properly powered up. If the packaged IC doesn't have basic functionality, the time intensive test suite supplied by an external tester would not be applied. As a result, testing time is saved by not applying an entire test suit to a packaged IC that doesn't pass basic functions.

A self-test by the IC itself may be performed using only power and a few signals supplied by the external test equipment. After a relatively short self-test is run by the packaged IC, the packaged IC would indicate whether the packaged IC passes the self test.

There is a need in the art to communicate the status of self-tests performed by packaged ICs. One embodiment of this invention communicates the status of a self-test by activating an LED mounted to the test socket. A detailed description of this embodiment of this invention is described later.

### SUMMARY OF THE INVENTION

An embodiment of this invention provides a circuit and method for improving testability and reducing test time for packaged integrated circuits. An LED is physically mounted to a test socket. One lead of the LED is electrically connected to a positive voltage through a pin on the socket. The other lead of the LED is electrically connected to a driving device physically located on the packaged IC. A packaged IC is inserted in the socket. The packaged IC runs a self-test on itself. If the self-test is positive, the driving device activates the LED.

Other aspects and advantages of the present invention will become apparent from the following detailed description, taken in conjunction with the accompanying drawing, illustrating by way of example the principles of the invention.

### BRIEF DESCRIPTION OF THE DRAWINGS

FIG. 1 is a mechanical drawing of a socket and light source viewed from the top.

FIG. 2 is a mechanical drawing of a socket and light source viewed from the top.

FIG. 3 is a mechanical drawing of a packaged IC being inserted into a socket.

FIG. 4 is a schematic drawing of an LED in series with a driving device.

FIG. 5 is a schematic drawing of an LED in series with a bipolar transistor.

FIG. 6 is a schematic drawing of an LED in series with a MOSFET.

### DETAILED DESCRIPTION OF THE PREFERRED EMBODIMENT

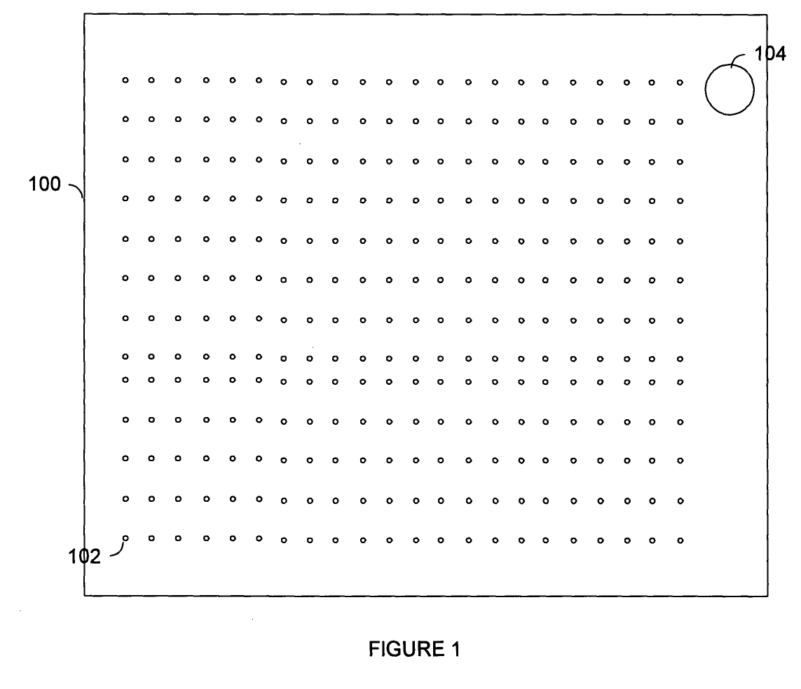

FIG. 1 is a mechanical drawing of a socket, 100 and light source, 104, viewed from the top. Socket holes, 102, are represented by small circles in FIG. 1. In this embodiment, the light source, 104 is physically mounted to the top of the socket, 100. The light source is electrically connected to two pins on the socket, 100.

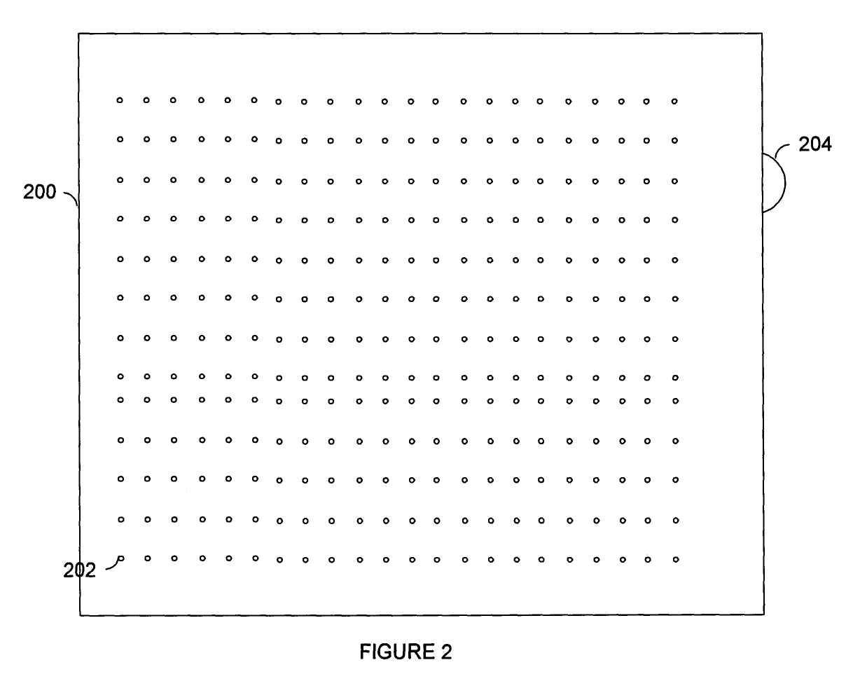

FIG. 2 is a mechanical drawing of a socket, 200 and light source, 204, viewed from the top. Socket holes, 202 are represented by small circles in FIG. 2. In this embodiment, the light source, 204, is physically mounted to the side of the socket, 200. The light source, 204 is electrically connected to two pins on the socket, 200.

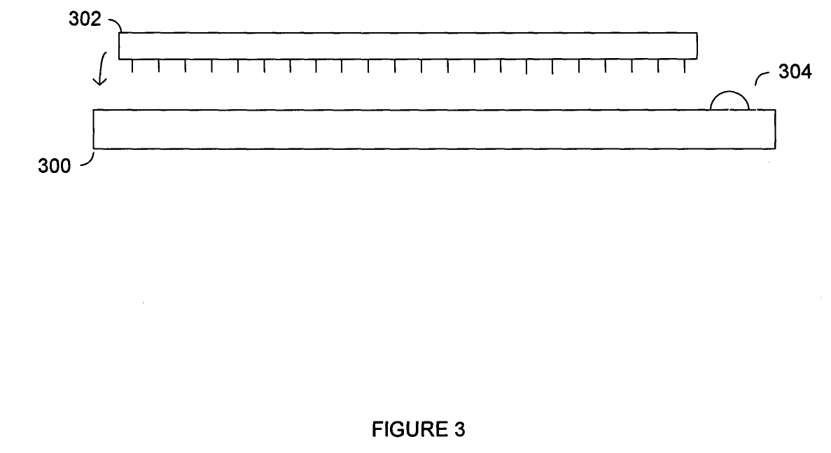

FIG. 3 is a mechanical drawing of a packaged IC, 302 being inserted into a socket, 300. After the packaged IC, 302 is inserted in the socket, 300, the packaged IC, 302, executes a self-test. In this example, if the self-test passes, the light source, 304, is activated, indicating to an operator that the packaged IC, 302, passes its self-test.

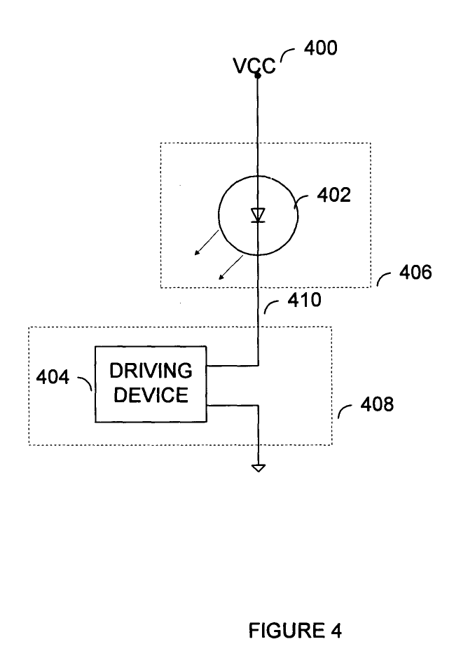

In FIG. 4, the light source, 402, is an LED. The dashed box, 406, around the LED, 402 indicates that the LED, 402 is mounted to a socket. The driving device, 404, is located on the IC. The dashed box, 408, indicates that the driving device, 404, is located on the IC. In this example, when the packaged IC passes a self-test, the driving device, 404 activates the LED, 402, by drawing current through the LED, 402. The leads of the LED, 402, are connected to pins on the socket. One pin is connected to a positive voltage, 400 and the other is connected to the driving device, 404 at node 410.

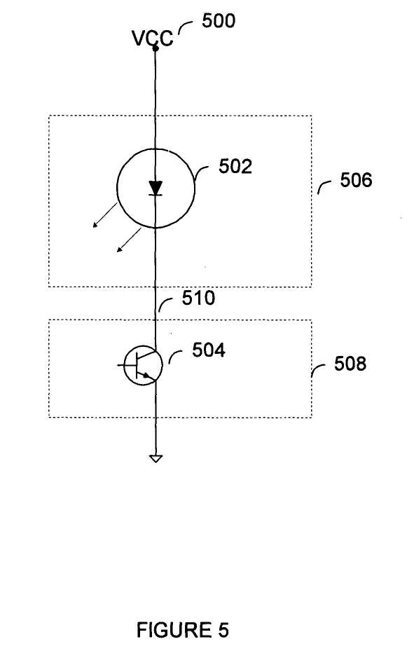

In FIG. 5, the light source, 502, is an LED. The dashed box, 506, around the LED, 502 indicates that the LED, 502 is mounted to a socket. The driving device, 504, is a bipolar transistor and is located on the IC. The dashed box, 508, indicates that the bipolar transistor, 504, is located on the IC. In this example, when the packaged IC passes a self-test, the bipolar transistor, 504 activates the LED, 502, by drawing current through the LED, 502. The leads of the LED, 502, are connected to pins on the socket. One pin is connected to a positive voltage, 500 and the other is connected to the bipolar transistor, 504 at node 510.

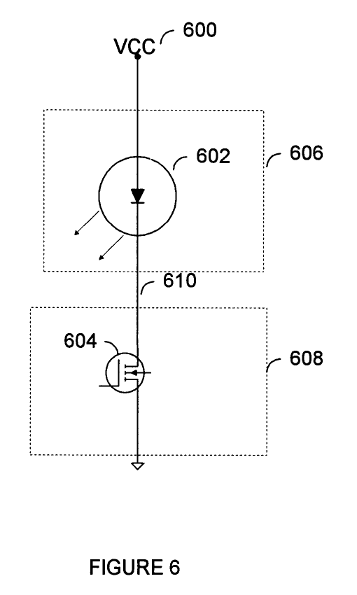

In FIG. 6, the light source, 602, is an LED. The dashed box, 606, around the LED, 602 indicates that the LED, 602 is mounted to a socket. The driving device, 604, is a MOSFET and is located on the IC. The dashed box, 608, indicates that the MOSFET, 604, is located on the IC. In this example, when the packaged IC passes a self-test, the MOSFET, 604 activates the LED, 602, by drawing current through the LED, 602. The leads of the LED, 602, are connected to pins on the socket. One pin is connected to a positive voltage, 600 and the other is connected to the MOSFET, 604 at node 610.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1) A system for indicating status of an IC self-test comprising:
a) a socket;
b) a light source, said light source physically and electrically connected to said socket;
c) wherein said light source is activated by an IC, said IC being inserted in said socket.

2) A system for indicating status of an IC self-test comprising:
a) a socket;
b) a light source, said light source physically mounted to said socket and electrically connected between a first pin and second pin on said socket;
c) wherein said light source is activated by an IC, said IC being inserted in said socket.

3) A system for indicating status of an IC self-test comprising:
a) a socket;
b) a light source, said light source physically mounted to said socket and electrically connected between a first pin and second pin on said socket;
c) wherein said first pin is connected to a positive voltage and said second pin is connected to a driving device on an IC, said IC being inserted in said socket;
d) wherein said driving device activates said light source.

4) The system in claim 3 wherein said light source is an LED.

5) The system in claim 3 wherein said driving device is a bipolar transistor.

6) The system in claim 3 wherein said driving device is a MOSFET.

7) The system in claim 3 wherein said driving device is a JFET.

8) A system for indicating status of an IC self-test comprising:
a) a socket;
b) an audio source, said audio source physically and electrically connected to said socket;
c) wherein said audio source is activated by an IC, said IC being inserted in said socket.

9) A system for indicating status of an IC self-test comprising:
a) a socket;
b) an audio source, said audio source physically mounted to said socket and electrically connected between a first pin and second pin on said socket;
c) wherein said audio source is activated by an IC, said IC being inserted in said socket.

10) A system for indicating status of an IC self-test comprising:
a) a socket;
b) an audio source, said audio source physically mounted to said socket and electrically connected between a first pin and second pin on said socket;
c) wherein said first pin is connected to a positive voltage and said second pin is connected to a driving device on an IC, said IC being inserted in said socket;
d) wherein said driving device activates said audio source.

11) The system in claim 10 wherein said audio source is a piezo-electric buzzer.

12) The system in claim 10 wherein said driving device is a bipolar transistor.

13) The system in claim 10 wherein said driving device is a MOSFET.

14) The system in claim 10 wherein said driving device is a JFET.

15) A method for indicating status of an IC self-test comprising:
a) physically mounting a light source to a socket;
b) electrically connecting said light source between a first pin and a second pin on said socket, said socket being connected to an external tester;
c) inserting an IC in said socket;
d) providing a positive voltage to said first pin;
e) connecting said second pin to a driving device on said IC;
f) applying a set of signals from said external tester to create said self-test on said IC;
g) wherein said driving device activates said light source if said self-test does not pass.

16) The method in claim 15 wherein said light source is an LED.

17) The system in claim 15 wherein said driving device is a bipolar transistor.

18) The system in claim 15 wherein said driving device is a MOSFET.

19) The system in claim 15 wherein said driving device is a JFET.

20) A method for indicating status of an IC self-test comprising:
a) physically mounting a light source to a socket;
b) electrically connecting said light source between a first pin and a second pin on said socket, said socket being connected to an external tester;
c) inserting an IC in said socket;
d) providing a positive voltage to said first pin;
e) connecting said second pin to a driving device on said IC;
f) applying a set of signals from said external tester to create said self-test on said IC;
g) wherein said driving device activates said light source if said self-test does pass.

21) The method in claim 20 wherein said light source is an LED.

22) The system in claim 20 wherein said driving device is a bipolar transistor.

23) The system in claim 20 wherein said driving device is a MOSFET.

24) The system in claim 20 wherein said driving device is a JFET.

25) A method for indicating status of an IC self-test comprising:
a) physically mounting an audio source to a socket;
b) electrically connecting said audio source between a first pin and a second pin on said socket, said socket being connected to an external tester;
c) inserting an IC in said socket;
d) providing a positive voltage to said first pin;
e) connecting said second pin to a driving device on said IC;
f) applying a set of signals from said external tester to create said self-test on said IC;
g) wherein said driving device activates said audio source if said self-test does not pass.

26) The method in claim 25 wherein said audio source is a piezo-electric buzzer.

27) A method for indicating status of an IC self-test comprising:
a) physically mounting an audio source to a socket;
b) electrically connecting said audio source between a first pin and a second pin on said socket, said socket being connected to an external tester;
c) inserting an IC in said socket;
d) providing a positive voltage to said first pin;
e) connecting said second pin to a driving device on said IC;
f) applying a set of signals from said external tester to create said self-test on said IC;
g) wherein said driving device activates said audio source if said self-test does pass.

28) The method in claim 27 wherein said audio source is a piezo-electric buzzer.

29) A system for indicating status of an IC self-test comprising:
a) a means for connecting a packaged IC to an external tester;
b) a means for creating light, said means for creating light physically and electrically connected to said means for connecting a packaged IC to an external tester;
c) wherein said means for creating light is activated by an IC, said IC being inserted in said means for connecting a packaged IC to an external tester.
